(19) United States
(12) Patent Application Publication
(10) Pub. No.: US 2026/0339193 A1
(43) Pub. Date: Oct. 29, 2026

(54) EUV MASK, METHOD FOR FORMING THE SAME, AND METHOD OF LITHOGRAPHY SYSTEM

(71) Applicants: TAIWAN SEMICONDUCTOR MANUFACTURING COMPANY, LTD., Hsinchu (TW); NATIONAL YANG MING CHIAO TUNG UNIVERSITY, Hsinchu City (TW)

(72) Inventors: Po-Hsun FANG, New Taipei City (TW); Po Kai CHANG, New Taipei City (TW); Lee-Feng CHEN, New Taipei City (TW); Yen-Liang CHEN, Hsinchu County (TW); Peichen YU, Hsinchu City (TW)

(73) Assignees: TAIWAN SEMICONDUCTOR MANUFACTURING COMPANY, LTD., Hsinchu (TW); NATIONAL YANG MING CHIAO TUNG UNIVERSITY, Hsinchu City (TW)

(21) Appl. No.: 19/189,798

(22) Filed: Apr. 25, 2025

(51) Int. Cl. G03F 1/24; G03F 1/58; G03F 1/80; G03F 7/00

(52) U.S. Cl. CPC G03F 1/24; G03F 1/58; G03F 1/80; G03F 7/7085

(57) ABSTRACT

A method includes forming a reflective multilayer over a substrate; forming a capping layer over the reflective multilayer; and forming an absorber layer over the capping layer, wherein the absorber comprises a first material having a reflectivity R1 satisfying:

$${R}_{1} = exp ( \frac{- 2 {πε}_{1}}{1 - {n}_{1}} ) \geq 50 \%$$

wherein n1 is a refractive index of the first material and ε_{1 is an extinction coefficient of the first material.}

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of lithography system in accordance with some embodiments of the present disclosure.

FIGS. 2A to 2D illustrate a method of patterning a layer in accordance with some embodiments of the present disclosure.

FIGS. 3A to 3D illustrate a method of patterning a layer in accordance with some embodiments of the present disclosure.

FIG. 4A is a cross-sectional view of an EUV mask in accordance with some embodiments of the present disclosure.

FIG. 4B is a refractive index (n) versus extinction coefficient (¿) plot in accordance with some embodiments of the present disclosure.

FIG. 5A is a cross-sectional view of an EUV mask in accordance with some embodiments of the present disclosure.

FIG. 5B is a refractive index (n) versus extinction coefficient (ε) plot in accordance with some embodiments of the present disclosure.

FIG. 6A is a cross-sectional view of an EUV mask in accordance with some embodiments of the present disclosure.

FIG. 6B is a refractive index (n) versus extinction coefficient (ε) plot in accordance with some embodiments of the present disclosure.

FIGS. 7A to 7D illustrate a method of forming an EUV mask in accordance with some embodiments of the present disclosure.

FIGS. 8A and 8B are schematic views of light source on a pupil plane in accordance with some embodiments of the present disclosure.

FIG. 8C is a light source size (σ) versus k1 factor plot in accordance with some embodiments of the present disclosure.

FIGS. 9A and 9B are schematic views of light source on a pupil plane in accordance with some embodiments of the present disclosure.

FIG. 9C is a light source size (σ) versus k1 factor plot in accordance with some embodiments of the present disclosure.

FIG. 10A is a schematic view of a pattern of an EUV mask in accordance with some embodiments of the present disclosure.

FIG. 10B is schematic views of light source on a pupil plane in accordance with some embodiments of the present disclosure.

FIG. 11A is a schematic view of a pattern of an EUV mask in accordance with some embodiments of the present disclosure.

FIG. 11B is schematic views of light source on a pupil plane in accordance with some embodiments of the present disclosure.

FIG. 12 illustrates a method for operating a lithography system in accordance with some embodiments of the disclosure.

FIG. 13 illustrates a lithography method in accordance with some embodiments of the disclosure.

FIG. 14 illustrates schematic views at various stages of a lithography method in accordance with some embodiments of the disclosure.

FIG. 15 illustrates an apparatus for operating a lithography system in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

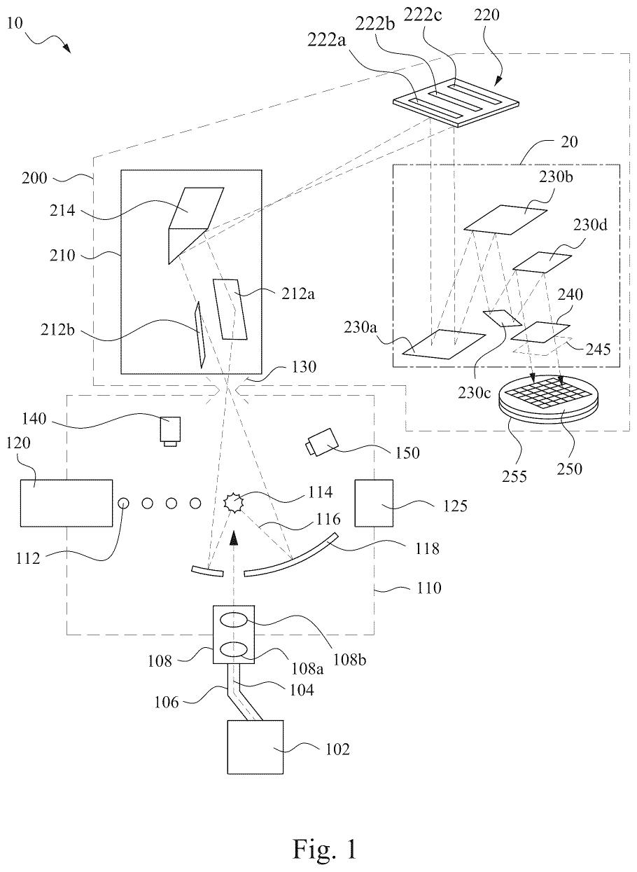

FIG. 1 is a schematic view of lithography system in accordance with some embodiments of the present disclosure. Shown there is a EUV lithography system 10. Although the EUV lithography system 10 is illustrated as having a certain configuration of components, it will be appreciated that the disclosed lithography system 10 may include additional components (e.g., additional mirrors) or having less components (e.g., less mirrors).

The EUV lithography system 10 includes a EUV source vessel 110. A fuel droplet generator 120 is connected to the EUV source vessel 110 and is configured to generate a plurality of fuel droplets 112. In some embodiments, the fuel droplets 112 generated by the fuel droplet generator 120 are provided into the EUV source vessel 110. In some embodiments, the fuel droplets 112 may include tin (Sn). In other embodiments, the fuel droplets 112 may include a different metal material. In some embodiments, the EUV source vessel 110 can also be referred to as a radiation source, in which radiation source employs a laser produced plasma (LPP) mechanism to generate plasma and further generate EUV light from the plasma.

The EUV lithography system 10 may also include a droplet position detection system which may include a droplet imager 140 disposed in the EUV source vessel 110 that captures an image of one or more fuel droplets 112. The droplet imager 140 may provide this captured image to a droplet position detection feedback system (not shown), which can, e.g., generate a droplet position and trajectory in response to an analysis result of the captured image. The position detection feedback system can thus generate a droplet error in response to the generated droplet position and trajectory, e.g., based on a droplet-by-droplet basis, or on average. In some embodiments, the droplet imager 140 may include a fine droplet steering camera (FDSC), a droplet formation camera (DFC), and/or suitable devices.

The EUV lithography system 10 further includes a primary laser having a laser source 102 configured to produce a laser beam 104. In some embodiments, the laser source 102 may include a multi-stage laser having a plurality of stages configured to amplify laser light produced by a prior stage. The laser beam 104 passes through a beam transport system 106 configured to provide the laser beam to a focusing system 108. The focusing system 108 includes one or more lenses 108a, 108b and/or mirrors arranged within a beam line and configured to focus the laser beam 104. The laser beam 104 is output from the focusing system 108 to the EUV source vessel 110.

The laser beam 104 transmits through a collector mirror 118 located within the EUV source vessel 110. Then, the primary laser beam 104 generated by the laser source 102 intersects the fuel droplets 112. In some embodiments, the primary laser beam 104 may be a carbon dioxide (CO₂) laser. In other embodiments, the primary laser beam 104 may include alternative types of lasers. When the primary laser beam 104 strikes the fuel droplets 112, the primary laser beam 104 heats the fuel droplets 112 to a temperature. At the temperature, the fuel droplets 112 shed their electrons and become a plasma 114 including a plurality of ions. In some embodiments, the ions emit EUV radiation 116 (e.g., having a wavelength of approximately 13.3 nm to about 13.7 nm).

In some embodiments, the collector mirror 118 has a concave curvature. In some embodiments, the collector mirror 118 may include a multi-layer coating having alternating layers of different materials. For example, in some embodiments, the collector mirror 118 may include alternating layers of molybdenum and silicon configured to operate as a Bragg reflector. The concave curvature of the collector mirror 118 focuses the EUV radiation 116 generated by the plasma 114 toward an intermediate focus (IF) unit 130 within an exit aperture of the EUV source vessel 110. The intermediate focus unit 130 is located between the EUV source vessel 110 and a scanner 200 including optical elements configured to direct the EUV radiation 116 to a workpiece (e.g., a semiconductor substrate). In some embodiments, the intermediate focus unit 130 may include a cone shaped aperture configured to provide for separation of pressures between the EUV source vessel 110 and the scanner 200. In some embodiments, the intermediate focus unit 130 may extend into the scanner 200.

The EUV lithography system 10 may also include an EUV energy monitor 150 disposed in the EUV source vessel 110. The EUV energy monitor 150 is designed to monitor the EUV intensity or energy generated from the EUV source vessel 110. For example, the EUV energy monitor 150 includes an EUV sensing element, such as a diode, designed to be sensitive to the EUV light and configured to effectively detect the EUV light. In other examples, the EUV energy monitor 150 includes a plurality of diodes configured in an array to effectively detect the EUV light for monitoring purpose. In some embodiments, a dose error is calculated based on the sensed EUV intensity (or energy). For example, when the sensed EUV intensity (or energy) is below a predetermined threshold value, such situation can be referred to as a dose error. Generally, the dose error is related to the plasma instability, through monitoring the EUV intensity by the EUV energy monitor 150, the dose error can be extracted from the monitored EUV intensity. Therefore, when a dose error is occurred, it indicates that the plasma 114 is unstable.

In some embodiments, the EUV lithography system further includes a droplet collection element 125 disposed in the EUV source vessel 110 and located opposite to the droplet generator 120. The droplet collection element 125 is configured to collect fuel droplets 112 that are not vaporized during formation of the EUV radiation 116 and/or fragments of fuel droplets 112 generated during formation of the EUV radiation 116.

The EUV radiation 116 output from the EUV source vessel 110 is provided to a condenser 210 by way of the intermediate focus unit 130. In some embodiments, the condenser 210 includes first and second surfaces 212a and 212b configured to focus the EUV radiation 116, and a reflector 214 configured to reflect the EUV radiation 116 towards a photomask 220. The photomask 220 is configured to reflect the EUV radiation 116 to form a pattern on a surface of a wafer 250. To produce the pattern, the photomask 220 may include a plurality of absorptive features 222a, 222b, and 222c arranged on a front surface of the photomask 220. The plurality of absorptive features 222a, 222b, and 222c are configured to absorb the EUV radiation 116, such that the reflected rays of EUV radiation 116 conveys a patterned defined by the photomask 220.

The lithography system 10 also includes a projection optics module (or projection optics box (POB) 20 for imaging the pattern of the photomask 220 on a target (e.g., wafer 250). The POB 20 has refractive optics (such as for UV lithography system) or alternatively reflective optics (such as for EUV lithography system) in various embodiments. The light directed from the photomask 220, diffracted into various diffraction orders and carrying the image of the pattern defined on the mask, is collected by the POB 20. The POB 20 may include a magnification of less than one (thereby the size of the “image” on a target (such as the wafer 250) is smaller than the size of the corresponding “object” on the mask).

In some embodiments, the POB 20 conveys the EUV radiation 116 onto a layer of photoresist disposed on a surface of the wafer 250. The EUV radiation 116 irradiates particular regions of the layer of photoresist based on the pattern carried by the EUV radiation 116, and thus the layer of irradiated photoresist layer can be patterned after developing it. Therefore, subsequent processing can be performed on selected regions of the wafer 250.

In some embodiments, the EUV radiation 116 is filtered through POB 20 including a series of first to fourth mirrors 230a, 230b, 230c, and 230d, which serve as lenses to reduce a size of the pattern carried by the EUV radiation 116.

The lithography system 10 also includes a pupil phase modulator 240 to modulate optical phase of the EUV radiation 116 directed from the photomask 220 so that the EUV radiation 116 has a phase distribution on a projection pupil plane 245. In the optical module, there is a plane with field distribution corresponding to Fourier Transform of the object (the photomask 220 in the present case). This plane is referred to as projection pupil plane. The pupil phase modulator 240 provides a mechanism to modulate the optical phase of the EUV radiation 116 on the projection pupil plane 245. In some embodiments, the pupil phase modulator 240 includes a mechanism to tune the reflective mirrors 230a, 230b, 230c, and 230d of the POB 20 for phase modulation. For example, the mirrors 230a, 230b, 230c, and 230d of the POB 20 are switchable and are controlled to reflect the EUV light, thereby modulating the phase of the light through the POB 20.

In some embodiments, the pupil phase modulator 240 utilizes a pupil filter placed on the projection pupil plane. A pupil filter filters out specific spatial frequency components of the EUV radiation 116 from the photomask 220. The pupil filter is a phase pupil filter that functions to modulate phase distribution of the light directed through the POB 20.

The lithography system 10 also includes a substrate stage 255 to secure the wafer 250 to be patterned. In some embodiments, the semiconductor substrate is a semiconductor wafer, such as a silicon wafer or other type of wafer. The wafer 250 is coated with the resist layer sensitive to the radiation beam, such as EUV light in the present embodiment. Various components including those described above are integrated together and are operable to perform lithography exposing processes. The lithography system 10 may further include other modules or may be integrated with (or be coupled with) other modules.

The photomask 220 and the method making the same are further described in accordance with some embodiments. In some embodiments, the mask fabrication process includes two operations: a blank mask fabrication process and a mask patterning process. During the blank mask fabrication process, a blank mask is formed by deposing suitable layers (e.g., reflective multiple layers) on a suitable substrate. The blank mask is then patterned during the mask patterning process to achieve a desired design of a layer of an integrated circuit (IC). The patterned mask is then used to transfer circuit patterns (e.g., the design of a layer of an IC) onto a semiconductor wafer. The patterns can be transferred over and over onto multiple wafers through various lithography processes. A set of masks is used to construct a complete IC.

The photomask 220 includes a suitable structure, such as a binary intensity mask (BIM), phase-shifting mask (PSM), or a phase-only mask (POM) in various embodiments. An example BIM includes absorptive regions (also referred to as opaque regions) and reflective regions, patterned to define an IC pattern to be transferred to the target. In the opaque regions, an absorber is present, and an incident light is almost fully absorbed by the absorber. In the reflective regions, the absorber is removed and the incident light is diffracted by a multilayer (ML).

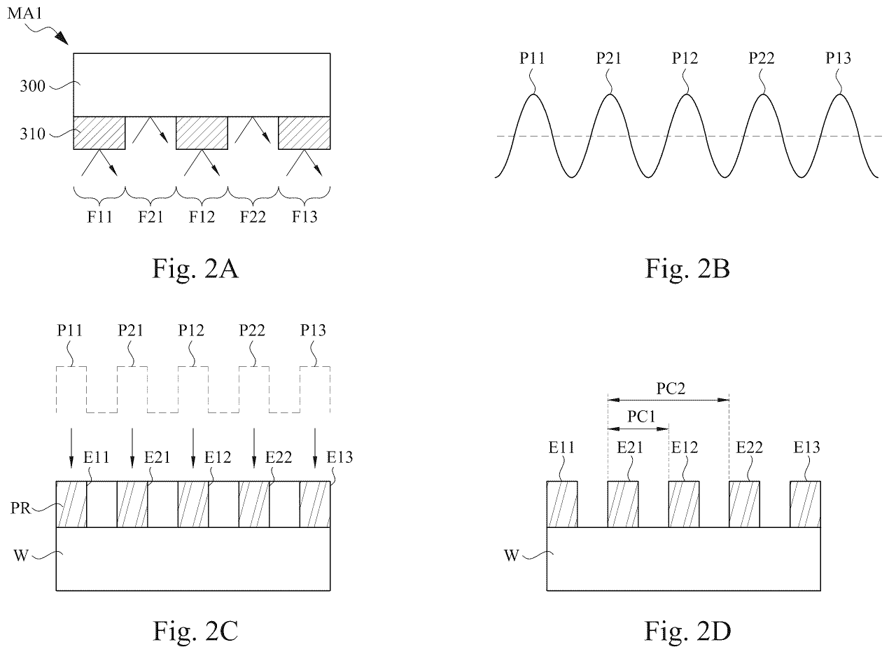

FIGS. 2A to 2D illustrate a method of patterning a layer in accordance with some embodiments of the present disclosure. In greater detail, FIG. 2A is a schematic view of an EUV mask, FIG. 2B is a light intensity distribution on a pupil plane, FIGS. 2C and 2D are schematic views of a wafer. In some embodiments, FIGS. 2A to 2D illustrate a method of patterning a photoresist layer PR over a wafer by using a phase-only mask (POM).

Reference is made to FIG. 2A. Shown there is an EUV mask MA1. In some embodiments, the EUV mask MA1 is a phase-only mask (POM), which includes a reflective multilayer (ML) 300 and a first material 310 over the reflective ML 300. In some embodiments, the first material 310 includes pattern features F11, F12, and F13 separated from each other in the cross-sectional view of FIG. 2A. The pattern features F11, F12, and F13 of the first material 310 covers portions of the reflective ML 300, in which portions of the reflective ML 300 that are not covered by the pattern features F11, F12, and F13 of the first material 310 may include pattern features F21 and F22. In greater detail, the pattern feature F21 of the reflective M L300 is between the pattern features F11 and F12 of the first material 310, and the pattern feature F22 of the reflective ML 300 is between the pattern features F12 and F13 of the first material 310.

The EUV mask M A 1 can be used as the photomask 220 in the lithography system 10 as discussed in FIG. 1, and the EUV mask M A 1 can pattern and reflect EUV radiation, so as to direct the patterned EUV radiation onto a wafer (e.g., wafer 250 in FIG. 1). In some embodiments, when the EUV mask M A 1 is a binary intensity mask (BIM), the first material 310 of the EUV mask M A 1 may be an absorber material, where the incident EUV radiation may be fully absorbed by the absorber material. However, the first material 310 of the EUV mask M A 1 can be selected to have reflectivity that is at least greater than 50%, such that at least 50% of the EUV radiation will be reflected by the first material 310 of the EUV mask MA1. Accordingly, as can be seen in FIG. 2A, the first material 310 and the reflective M L300 both reflect the EUV radiation. In some embodiments, the first material 310 may also absorb a portion of the EUV radiation, and thus the first material 310 can also be referred to as an absorber layer.

Reference is made to FIG. 2B, in which FIG. 2B is a light intensity distribution on a pupil plane. In some embodiments, the EUV radiation that is patterned and reflected by the EUV mask M A 1 is detected at a pupil plane (e.g., the pupil plane 245 in FIG. 1). As shown in FIG. 2B, the light intensity distribution of the EUV radiation includes peaks P11, P12, P13, P21, and P22, in which the peaks P11, P12, P13 may correspond to the pattern features F11, F12, and F13 of the first material 310, and the peaks P21 and P22 may correspond to the pattern features F21 and F22 of the reflective ML 300, respectively. In some embodiments, a threshold intensity (see dashed line in FIG. 2B) is set, such that only the light intensity above this threshold can be directed to a wafer (e.g., wafer W in FIG. 2C).

Reference is made to FIG. 2C. The patterned EUV radiation is directed to a wafer W where a photoresist layer PR is coated thereon, such that the photoresist layer PR may include exposed regions E11, E12, E13, E21, and E22. In greater detail, the exposed regions E11, E12, E13, E21, and E22 of the photoresist layer PR may correspond to the peaks P11, P12, P13, P21, and P22 of the light distribution of the EUV radiation as shown by dashed line. More specifically, the patterns of the exposed regions E11, E12, E13 of the photoresist layer PR may correspond to the pattern features F11, F12, and F13 of the first material 310, and the patterns of the exposed regions E21 and E22 of the photoresist layer PR may correspond to the pattern features F21 and F22 of the reflective ML 300, respectively.

Reference is made to FIG. 2D. After the photoresist layer PR on the wafer W is exposed through the patterned EUV radiation, a development process may be performed to remove portions of the photoresist layer PR. In some embodiments where the photoresist layer PR is a negative-type photoresist, the non-exposed regions of the photoresist layer PR may be removed as a result of the development process. Accordingly, the exposed regions E11, E12, E13, E21, and E22 of the photoresist layer PR may remain over the wafer W. The patterns of the patterned photoresist layer PR can be transferred to a material over the wafer W, such as a dielectric layer, a conductive layer, a semiconductor layer, etc. For example, an etching process may be performed to remove portions of the material over the wafer W through the photoresist layer PR, so as to create several features, which correspond to the exposed regions E11, E12, E13, E21, and E22 of the photoresist layer PR, over the wafer W.

As shown in FIG. 2D, the patterns of the patterned photoresist layer PR may include a line pitch PC1. For example, the line pitch PC1 can be regarded as a distance between a sidewall of the exposed region E21 of the photoresist layer PR and the exposed regions E12 of the photoresist layer PR.

In some embodiments where the EUV mask MA1 as discussed in FIG. 2A is a binary intensity mask (BIM), the first material 310 of the EUV mask MA1 may be an absorber material, in which the incident EUV radiation may be fully absorbed by the absorber material. In such embodiments, the pattern features F11, F12, and F13 of the first material 310 may not reflect the EUV radiation. Accordingly, the peaks P11, P12, and P13 may not present in the light intensity distribution of FIG. 2B. That is, only the peaks P21 and P22 will be present in the light intensity distribution of FIG. 2B. As a result, the regions E11, E12, and E13 of photoresist layer PR may not be exposed as shown in FIG. 2C, and the regions E11, E12, and E13 of photoresist layer PR will not be present in the structure shown in FIG. 2D after the development process is complete. That is, when the EUV mask MA1 as discussed in FIG. 2A is a binary intensity mask (BIM), only the exposed regions E21 and E22 of photoresist layer PR will remain in the structure shown in FIG. 2D. In such embodiments, the patterns of the patterned photoresist layer PR may include a line pitch PC2. For example, the line pitch PC2 can be regarded as a distance between a sidewall of the exposed region E21 of the photoresist layer PR and the exposed regions E22 of the photoresist layer PR. It can be seen that the line pitch PC2 is greater than the line pitch PC1. In some embodiments, the line pitch PC2 is twice the line pitch PC1. Based on the above discussion, by using a phase-only mask in an EUV process, it is possible to achieve a light intensity distribution having a double frequency comparing with a binary intensity mask, such double frequency effect makes it possible to decrease the mask minimum pitch. For example, if a common EUV mask can print a minimum pitch (p) on a substrate, the phase-only mask can print a minimum pitch (p/2) on the substrate. That is, by using the phase-only mask, it is possible to reduce the minimum pitch by 1/2.

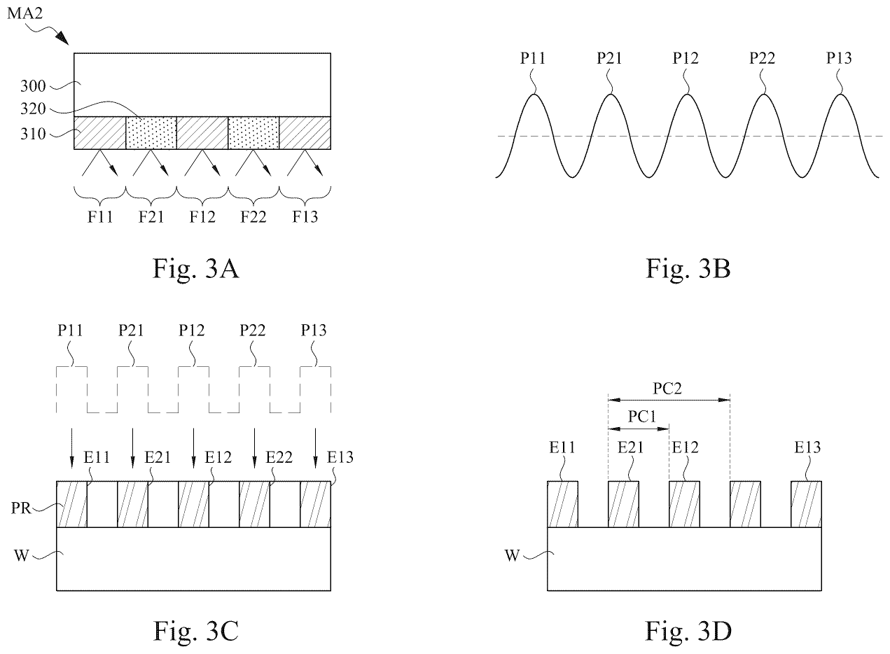

FIGS. 3A to 3D illustrate a method of patterning a layer in accordance with some embodiments of the present disclosure. In greater detail, FIG. 3A is a schematic view of an EUV mask, FIG. 3B is a light intensity distribution on a pupil plane, FIGS. 3C and 3D are schematic views of a wafer. In some embodiments, FIGS. 3A to 3D illustrate a method of patterning a photoresist layer PR over a wafer by using a phase-only mask (POM). Some elements of FIGS. 3A to 3D may be similar to those described in FIGS. 2A to 2D, such elements are labeled the same, and relevant details will not be repeated for brevity.

In FIG. 3A, shown there is an EUV mask MA2. In some embodiments, the EUV mask M A 2 is a phase-only mask (POM), which includes a reflective multilayer (ML) 300, a first material 310, and a second material 320 over the reflective ML 300, in which the first material 310 is different from the second material 320. In some embodiments, the first material 310 includes pattern features F11, F12, and F13, and the second material 320 includes pattern features F21 and 22. In greater detail, the pattern feature F21 of the second material 320 is between the pattern features F11 and F12 of the first material 310, and the pattern feature F22 of the second material 320 is between the pattern features F12 and F13 of the first material 310.

The EUV mask M A 2 can be used as the photomask 220 in the lithography system 10 as discussed in FIG. 1, and the EUV mask MA2 can pattern and reflect EUV radiation, so as to direct the patterned EUV radiation onto a wafer (e.g., wafer 250 in FIG. 1). The first material 310 and the second material 320 of the EUV mask MA2 can be selected to have reflectivity that is at least greater than 50%, such that at least 50% of the EUV radiation will be reflected by the first material 310 and the second material 320 of the EUV mask MA2. Accordingly, as can be seen in FIG. 3A, the first material 310 and the second material 320 both reflect the EUV radiation. In some embodiments, the first material 310 and the second material 320 may also absorb a portion of the EUV radiation, and thus the first material 310 and the second material 320 can be collectively referred to as an absorber layer.

Reference is made to FIG. 3B, in which FIG. 3B is a light intensity distribution on a pupil plane. In some embodiments, the EUV radiation that is patterned and reflected by the EUV mask M A 2 is detected at a pupil plane (e.g., the pupil plane 245 in FIG. 1). As shown in FIG. 3B, the light intensity distribution of the EUV radiation includes peaks P11, P12, P13, P21, and P22, in which the peaks P11, P12, P13 may correspond to the pattern features F11, F12, and F13 of the first material 310, and the peaks P21 and P22 may correspond to the pattern features F21 and F22 of the second material 320, respectively. In some embodiments, a threshold intensity (see dashed line in FIG. 3B) is set, such that only the light intensity above this threshold can be directed to a wafer (e.g., wafer W in FIG. 3C).

Reference is made to FIG. 3C. The patterned EUV radiation is directed to a wafer W where a photoresist layer PR is coated thereon, such that the photoresist layer PR may include exposed regions E11, E12, E13, E21, and E22. In greater detail, the exposed regions E11, E12, E13, E21, and E22 of the photoresist layer PR may correspond to the peaks P11, P12, P13, P21, and P22 of the light distribution of the EUV radiation as shown by dashed line. More specifically, the patterns of the exposed regions E11, E12, E13 of the photoresist layer PR may correspond to the pattern features F11, F12, and F13 of the first material 310, and the patterns of the exposed regions E21 and E22 of the photoresist layer PR may correspond to the pattern features F21 and F22 of the second material 320, respectively.

Reference is made to FIG. 3D. After the photoresist layer PR on the wafer W is exposed through the patterned EUV radiation, a development process may be performed to remove portions of the photoresist layer PR. In some embodiments where the photoresist layer PR is a negative-type photoresist, the non-exposed regions of the photoresist layer PR may be removed as a result of the development process. Accordingly, the exposed regions E11, E12, E13, E21, and E22 of the photoresist layer PR remain over the wafer W. The patterns of the patterned photoresist layer PR can be transferred to a material over the wafer W, such as a dielectric layer, a conductive layer, a semiconductor layer, etc. For example, an etching process may be performed to remove portions of the material over the wafer W through the photoresist layer PR, so as to create several features, which correspond to the exposed regions E11, E12, E13, E21, and E22 of the photoresist layer PR, over the wafer W.

As shown in FIG. 3D, the patterns of the patterned photoresist layer PR may include a line pitch PC1. For example, the line pitch PC1 can be regarded as a distance between a sidewall of the exposed region E21 of the photoresist layer PR and the exposed regions E12 of the photoresist layer PR.

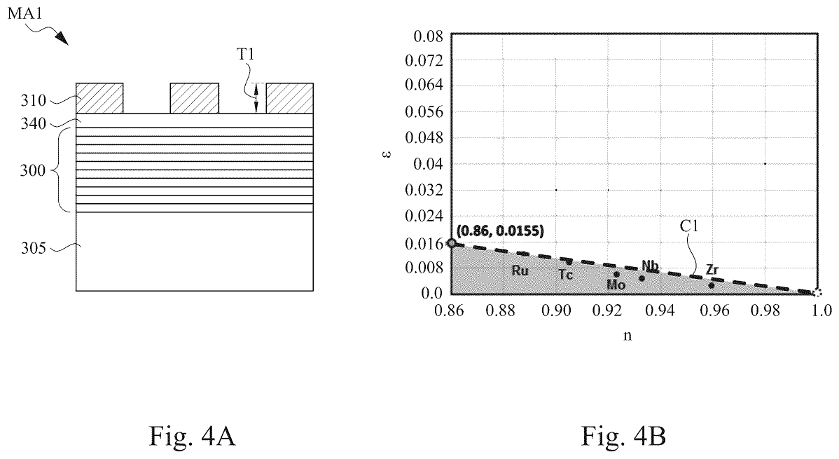

FIG. 4A is a cross-sectional view of an EUV mask in accordance with some embodiments of the present disclosure. FIG. 4B is a refractive index (n) versus extinction coefficient (ε) plot in accordance with some embodiments of the present disclosure. FIG. 4A illustrates exemplary embodiments of the EUV mask M A 1 as discussed in FIGS. 2A to 2D.

The EUV mask M A 1 includes a substrate 305. The substrate 305 may be made of low thermal expansion material (LTEM), and thus can also be referred to as a LTEM substrate. In some embodiments, the LTEM material includes TiO₂, doped SiO₂, and/or other low thermal expansion materials known in the art. The substrate 305 serves to minimize image distortion due to mask heating. In some embodiments, a conductive layer (not shown) may be deposited at the bottom surface the substrate 305 for electrostatic chucking the mask. In some embodiments, the conductive layer includes chromium nitride (CrN), though other compositions are possible.

The EUV mask M A 1 further includes a reflective multilayer (ML) 300 deposited over the substrate 305. According to Fresnel equations, light reflection will occur when light propagates across the interface between two materials of different refractive indices. The reflected light is larger when the difference of refractive indices is larger. To increase the reflected light, one may also increase the number of interfaces by deposing a multilayer of alternating materials and let light reflected from different interfaces interfere constructively by choosing appropriate thickness for each layer inside the multilayer. However, the absorption of the employed materials for the multilayer limits the highest reflectivity that can be achieved. The reflective ML 300 includes a plurality of film pairs, such as molybdenum-silicon (M o/Si) film pairs (e.g., a layer of molybdenum above or below a layer of silicon in each film pair). Alternatively, the reflective ML 300 may include molybdenum-beryllium (M o/Be) film pairs, or any material pair that is highly reflective at EUV wavelengths can be utilized for the reflective ML 300. The thickness of each layer of the reflective ML 300 depends on the EUV wavelength and the incident angle. The thickness of the reflective ML 300 is adjusted to achieve a maximum constructive interference of the EUV light reflected at each interface and a minimum absorption of the EUV light by the reflective ML 300. The reflective ML 300 may be selected such that it provides a high reflectivity to a selected radiation type/wavelength. A typical number of film pairs is 20-80, however any number of film pairs is possible. The reflective ML 300 usually achieves a reflectivity of 65% or above.

The EUV mask MA1 may also include a capping layer 340 disposed above the reflective ML 300 to prevent oxidation of the reflective ML 300. In some embodiments, the capping layer 340 includes ruthenium (Ru), Ru compounds such as RuB, RuSi, chromium (Cr), Cr oxide, and Cr nitride.

The EUV mask MA1 may include a first material 310 over the top surface of the capping layer 340. In some embodiments, the first material 310 may include a thickness T1 in a range from about 10 nm to about 70 nm. The first material 310 may include openings that expose portions of the capping layer 340. If the EUV mask M A 1 is used for a phase-only mask (POM) purpose as discussed in FIGS. 2A to 2D, the material of the first material 310 may be selected to have a reflectivity at least greater than or equal to 50%. In some embodiments, the reflectivity of the first material 310 can be expressed as:

$${R}_{1} = exp ( \frac{- 2 π {ε}_{1}}{1 - {n}_{1}} ) \geq 50 \%$$

Here, R₁ is the reflectivity of the material of the first material 310, n₁ is the refractive index of the material of the first material 310, and ε₁ is the extinction coefficient of the material of the first material 310. Accordingly, the material of the first material 310 may be selected to have a refractive index n₁ and an extinction coefficient ε₁ that satisfy the above equation, such that the reflectivity R₁ of the material of the first material 310 is greater than or equal to 50%.

FIG. 4B is a refractive index (n) versus extinction coefficient (ε) plot, in which the lateral axis (X-axis) represents refractive index (n), and the vertical axis (Y-axis) represents extinction coefficient (ε). FIG. 4B illustrates a curve C1, in which the curve C1 is determined by setting the reflectivity R₁ of the above equation is equal to 50%, and the formula of the curve C1 can be expressed as:

$${ε}_{1} = ln ( 0.5 ) \times \frac{( 1 - {n}_{1} )}{- 2 π}$$

In the n-k plot shown FIG. 4B, a material which includes a refractive index and an extinction coefficient that is below the curve C1 (or within the region enclosed by the lateral axis, the vertical axis, and the curve C1) may satisfy the above equation. Accordingly, such materials can be possible candidates of the first material 310. In some embodiments where the thickness T1 of the first material 310 is in a range from about 10 nm to about 70 nm, possible candidates of the first material 310 may include ruthenium (Ru), technetium (Tc), molybdenum (M o), niobium (Nb), zirconium (Zr), etc.

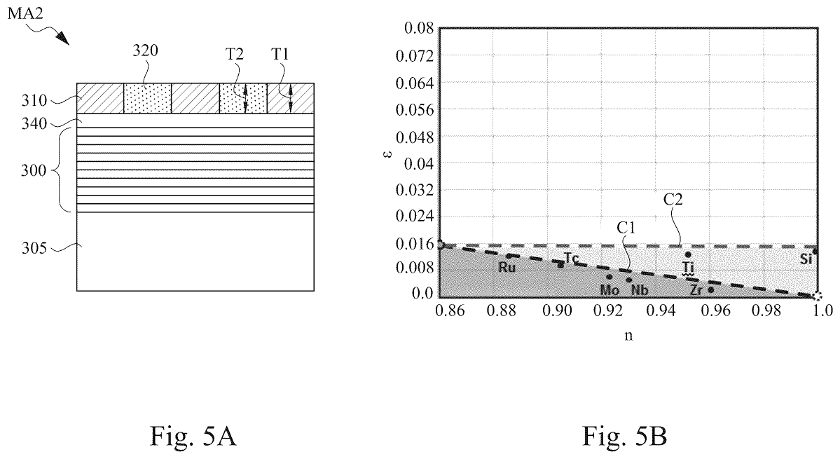

FIG. 5A is a cross-sectional view of an EUV mask in accordance with some embodiments of the present disclosure. FIG. 5B is a refractive index (n) versus extinction coefficient (ε) plot in accordance with some embodiments of the present disclosure. FIG. 5A illustrates exemplary embodiments of the EUV mask M A 2 as discussed in FIGS. 3A to 3D. It is noted that some elements of FIG. 5A may be similar to those described in FIG. 4A, such elements are labeled the same, and relevant details will not be repeated for brevity.

The EUV mask MA2 includes a substrate 305, a reflective ML 300 over the substrate 305, a capping layer 340 over the reflective ML 300. The EUV mask MA2 further includes a first material 310 and a second material 320 over the top surface of the capping layer 340. In some embodiments, the first material 310 and the second material 320 include a thickness T1 and a thickness T2, respectively, in which the thicknesses T1 and T2 are in a range from about 10 nm to about 70 nm. In such embodiments, the first material 310 and the second material 320 may include the same thickness. If the EUV mask M A 2 is used for a phase-only mask (POM) purpose as discussed in FIGS. 3A to 3D, the material of the first material 310 may be selected to have a reflectivity at least greater than or equal to 50%. In some embodiments, the reflectivity of the first material 310 can be expressed as:

$${R}_{1} = exp ( \frac{- 2 π {ε}_{1}}{1 - {n}_{1}} ) \geq 50 \%$$

Here, R₁ is the reflectivity of the material of the first material 310, n₁ is the refractive index of the material of the first material 310, and ε₁ is the extinction coefficient of the material of the first material 310. Accordingly, the material of the first material 310 may be selected to have a refractive index n₁ and an extinction coefficient ε₁ that satisfy the above equation, such that the reflectivity R₁ of the material of the first material 310 is greater than or equal to 50%.

FIG. 5B is a refractive index (n) versus extinction coefficient (ε) plot, in which the lateral axis (X-axis) represents refractive index (n), and the vertical axis (Y-axis) represents extinction coefficient (ε). FIG. 5B illustrates a curve C1, in which the curve C1 is determined by setting the reflectivity R₁ of the above equation is equal to 50%, and the formula of the curve C1 can be expressed as:

$${ε}_{1} = ln ( 0.5 ) \times \frac{( 1 - {n}_{1} )}{- 2 π}$$

In the n-k plot shown FIG. 5B, a material which includes a refractive index and an extinction coefficient that is below the curve C1 (or within the region enclosed by the lateral axis, the vertical axis, and the curve C1) may satisfy the above equation. Accordingly, such materials can be possible candidates of the first material 310. In some embodiments where the thickness T1 of the first material 310 is in a range from about 10 nm to about 70 nm, possible candidates of the first material 310 may include ruthenium (Ru), technetium (Tc), molybdenum (Mo), niobium (Nb), zirconium (Zr), etc. In some embodiments, the first material 310 may be metal.

On the other hand, the material of the second material 320 may be selected to have a reflectivity at least greater than or equal to 50%. In some embodiments, the material of the second material 320 may include a different refractive index and a different extinction coefficient than the first material 310. Generally, the greater the difference in the refractive index between the first material 310 and the second material 320, the better. In some embodiments where the thickness T2 of the second material 320 is in a range from about 10 nm to about 70 nm. The material of the second material 320 can be selected to have a refractive index n₂ in a range from about 0.86 to about 0.999 (e.g., less than 1.0), and an extinction coefficient 82 in a range from about 0 to about 0.0155.

FIG. 5B illustrates a curve C2, in which the curve C2 can be expressed as 82=0.0155. In the n-k plot shown FIG. 5B, materials which include a refractive index and an extinction coefficient that is above the curve C1 and below the curve C2 can be possible candidates of the second material 320. That is, the material of the second material 320 may satisfy ε₁<ε₂<0.0155, in which ε₁ can be expressed as the equation above. In some embodiments where the thickness T2 of the second material 320 is in a range from about 10 nm to about 70 nm, possible candidates of the second material 320 may include titanium (Ti), silicon (Si), etc. In some embodiments where the second material 320 is made of silicon, the second material 320 is a semiconductor material.

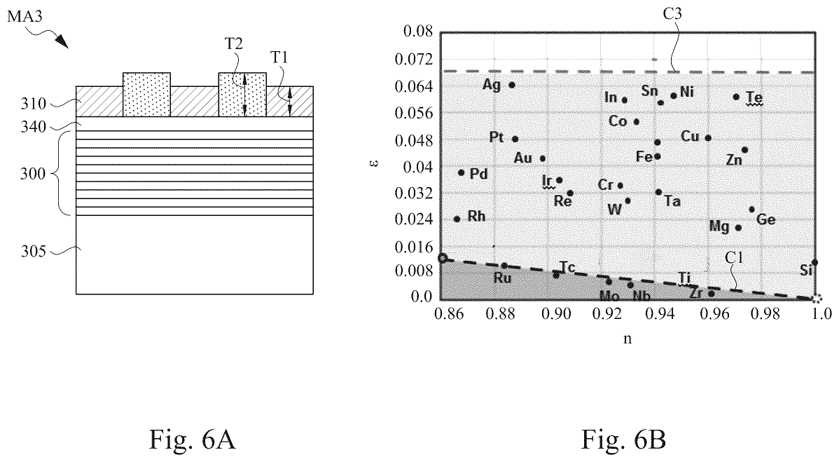

FIG. 6A is a cross-sectional view of an EUV mask in accordance with some embodiments of the present disclosure. FIG. 6B is a refractive index (n) versus extinction coefficient (ε) plot in accordance with some embodiments of the present disclosure. FIG. 6A illustrates an EUV mask M A 3 that is similar to the EUV mask M A 2 as discussed in FIG. 5A. The difference between the EUV mask MA3 of FIG. 6A and the EUV mask MA2 of FIG. 5A is that the first material 310 and the second material 320 of the EUV mask MA3 have different thicknesses. For example, the thickness T2 of the second material 320 is greater than the thickness T1 of the first material 310. In some embodiments, the thickness T1 of the first material 310 is in a range from about 10 nm to about 70 nm. On the other hand, the thickness T2 of the second material 320 is in a range from about 10 nm to about 200 nm.

If the EUV mask M A 3 is used for a phase-only mask (POM) purpose as discussed above, the material of the first material 310 may be selected to have a reflectivity at least greater than or equal to 50%. In some embodiments, the reflectivity of the first material 310 can be expressed as:

$${R}_{1} = exp ( \frac{- 2 π {ε}_{1}}{1 - {n}_{1}} ) \geq 50 \%$$

Here, R₁ is the reflectivity of the material of the first material 310, n₁ is the refractive index of the material of the first material 310, and ε₁ is the extinction coefficient of the material of the first material 310. Accordingly, the material of the first material 310 may be selected to have a refractive index n₁ and an extinction coefficient ε₁ that satisfy the above equation, such that the reflectivity R₁ of the material of the first material 310 is greater than or equal to 50%.

FIG. 6B is a refractive index (n) versus extinction coefficient (ε) plot, in which the lateral axis (X-axis) represents refractive index (n), and the vertical axis (Y-axis) represents extinction coefficient (ε). FIG. 6B illustrates a curve C1, in which the curve C1 is determined by setting the reflectivity R₁ of the above equation is equal to 50%, and the formula of the curve C1 can be expressed as:

$${ε}_{1} = ln ( 0.5 ) \times \frac{( 1 - {n}_{1} )}{- 2 π}$$

In the n-k plot shown FIG. 6B, a material which includes a refractive index and an extinction coefficient that is below the curve C1 (or within the region enclosed by the lateral axis, the vertical axis, and the curve C1) may satisfy the above equation. Accordingly, such materials can be possible candidates of the first material 310. In some embodiments where the thickness T1 of the first material 310 is in a range from about 10 nm to about 70 nm, possible candidates of the first material 310 may include ruthenium (Ru), technetium (Tc), molybdenum (M o), niobium (Nb), zirconium (Zr), etc.

On the other hand, the material of the second material 320 may be selected to have a reflectivity at least greater than or equal to 50%. In some embodiments, the material of the second material 320 may include a different refractive index and a different extinction coefficient than the first material 310. Generally, the greater the difference in the refractive index between the first material 310 and the second material 320, the better. In some embodiments where the thickness T2 of the second material 320 is in a range from about 10 nm to about 200 nm. The material of the second material 320 can be selected to have a refractive index n₂ in a range from about 0.86 to about 0.999 (e.g., less than 1.0), and a extinction coefficient 82 in a range from about 0 to about 0.864.

FIG. 6B illustrates a curve C3, in which the curve C3 can be expressed as 2=0.864. In the n-k plot shown FIG. 6B, materials which include a refractive index and an extinction coefficient that is above the curve C1 and below the curve C3 can be possible candidates of the second material 320. That is, the material of the second material 320 may satisfy ε₁<ε₂<0.864, in which ε₁ can be expressed as the equation above. In some embodiments where the thickness T2 of the second material 320 is in a range from about 10 nm to about 200 nm, possible candidates of the second material 320 may include titanium (Ti), silicon (Si), rhodium (Rh), palladium (Pd), platinum (Pt), silver (Ag), gold (Au), iridium (Ir), rhenium (Re), indium (In), cobalt (Co), chromium (Cr), tungsten (W), iron (Fe), tin (Sn), tantalum (Ta), copper (Cu), nickel (Ni), tellurium (Te), zinc (Zn), magnesium (Mg), germanium (Ge), etc.

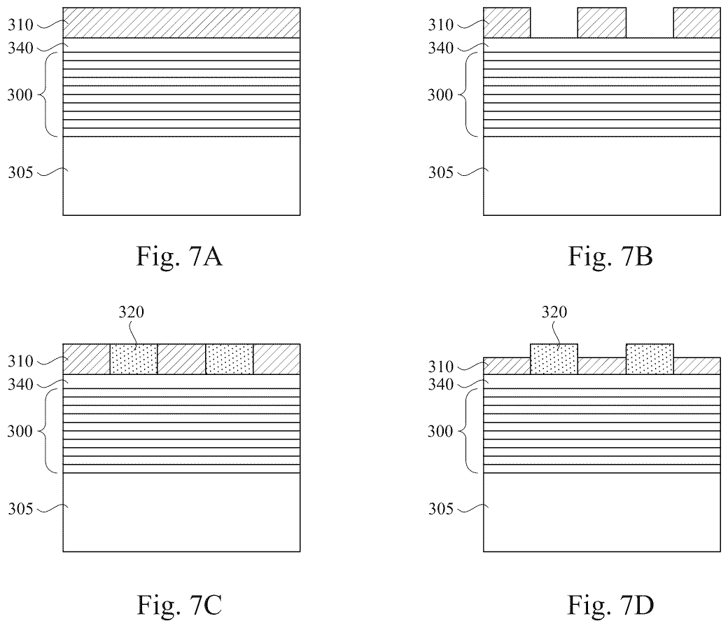

FIGS. 7A to 7D illustrate a method of forming an EUV mask in accordance with some embodiments of the present disclosure. It is noted that some elements of FIGS. 7A to 7D have been described above, such elements are labeled the same, and relevant details will not be repeated for brevity.

Reference is made to FIG. 7A. A reflective ML 300 is formed over a substrate 305, a capping layer 340 is formed over the reflective ML 300, and a first material 310 is formed over the capping layer 340. In some embodiments, one or more of the reflective ML 300, the capping layer 340, and the first material 310 may be formed by various methods, including physical vapor deposition (PV D) process such as evaporation and DC magnetron sputtering, a plating process such as electrode-less plating or electroplating, a chemical vapor deposition (CVD) process such as atmospheric pressure CVD (APCVD), low pressure CVD (LPCVD), plasma enhanced CVD (PECVD), or high density plasma CVD (HDP CVD), ion beam deposition, spin-on coating, metal-organic decomposition (MOD), and/or other methods known in the art.

Reference is made to FIG. 7B. The first material 310 is patterned to form the design layout having pattern features F11, F12, and F13. The first material 310 can be patterned by various patterning techniques. One such technique includes using a resist coating (e.g., spin-on coating), soft baking, mask aligning, exposure, post-exposure baking, developing the resist, rinsing, and drying (e.g., hard baking). An etching process follows to remove portions the first material 310. The etching process may include dry (plasma) etching, wet etching, and/or other etching methods. Alternative patterning processes include maskless photolithography, electron-beam writing, direct-writing, and/or ion-beam writing. In some embodiments, the EUV mask MA1 of FIG. 4A can be formed through the processes discussed in FIGS. 7A and 7B.

Reference is made to FIG. 7C. A second material 320 is formed over the substrate 305 and filling the openings within the first material 310. In some embodiments, the second material 320 can be deposited blanket over the substrate 305, and a planarization process can then be performed to remove excess material of the second material 320, such that top surfaces of the first material 310 and the second material 320 are substantially level with each other. In some embodiments, the EUV mask MA2 of FIG. 5A can be formed through the processes discussed in FIGS. 7A to 7C.

Reference is made to FIG. 7D. An etching back process is performed to lower top surface of the first material 310, resulting in the second material 320 being thicker than the first material 310. The etchant of the etching back process is selected to have a higher etching rate to the first material 310 than to the second material 320. In some embodiments, the EUV mask MA3 of FIG. 6A can be formed through the processes discussed in FIGS. 7A to 7D.

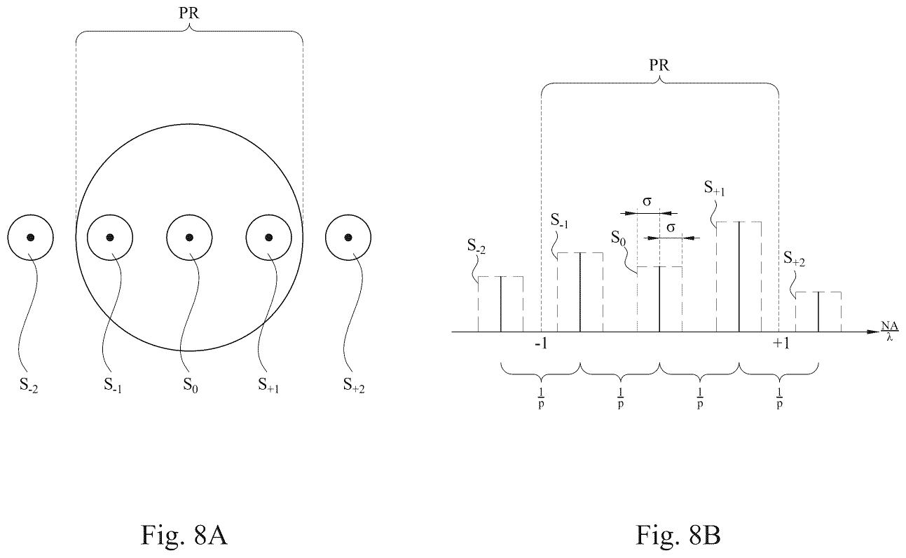

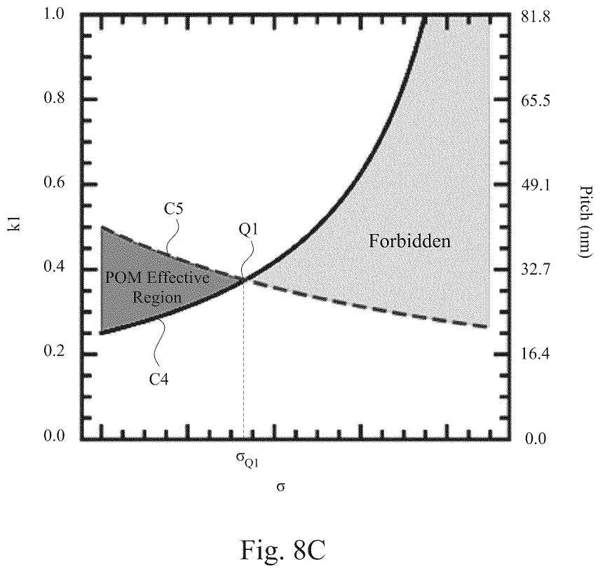

FIGS. 8A and 8B are schematic views of light source on a pupil plane in accordance with some embodiments of the present disclosure. Once an EUV mask (e.g., the EUV masks MA1, MA2, and M A 3 as discussed above) has been manufactured, the EUV mask can be used as the photomask 220 in the lithography system 10 as shown in FIG. 1. Generally, for a common EUV mask, the minimum pitch size (p) that can be printed on a semiconductor wafer (e.g., the wafer 250 of FIG. 1) may satisfy the Rayleigh criterion:

$$\frac{p}{2} = {k}_{1} \times \frac{λ}{N A} \qquad ( 1 )$$

λ is the wavelength of the light source used in the lithography system 10. In some embodiments, λ in the case of EUV is typically around 13.5 nanometers. NA represents the numerical aperture of the lithography system, which is a measure of its ability to gather light and resolve fine features. In some embodiments, NA in the case of EUV is typically around 0.33. The k₁ factor is a dimensionless value that encapsulates the various other parameters affecting resolution, including the process technology specifics, pattern fidelity, and aspects of the imaging system such as coherence and image contrast. It accounts for practical limitations and enhancements like advanced mask designs, optical proximity correction, and other strategies employed to push beyond traditional limits.

In some embodiments, the k₁ factor of the above equation can be calculated based on the experiment results. For example, when an EUV mask is manufactured, a lithography process can be performed using the EUV mask. Generally, the wavelength λ and the numerical aperture NA of a lithography system are fixed values, such as 13.5 nm and 0.33 in some embodiments. On the other hand, the critical dimension (CD) that can be printed on a semiconductor wafer can be determined based on the results of the lithography process. For example, when a layer over a wafer is patterned using the lithography system, the minimum line pitch (e.g., critical dimension; CD) can be detected based on the patterned layer. Accordingly, the k₁ factor of the lithography system with a given EUV mask can therefore be determined.

However, as discussed above, when the EUV mask is a phase-only mask (POM), the minimum pitch size can be reduced to p/2 (comparing with common EUV mask). Accordingly, the equation (1) can be expressed as:

$$\frac{p}{2 \times 2} = \frac{p}{4} = {k}_{1} \times \frac{λ}{N A} \qquad ( 2 )$$

As shown in FIG. 8A, when the EUV mask (e.g., the EUV masks MA1, MA2, and M A 3 as discussed) has a periodic structure, the periodic structure may diffract the light, such that the light source may include a 0 order light S₀, a+1 order light S₊₁, a−1 order light S₋₁, a+2 order light S₊₂, and a−2 order light S₋₂. Ideally, to obtain a double frequency effect from the EUV mask, it is desired that the 0 order light S₀, the +1 order light S₊₁, and the −1 order light S₋₁ are within the pupil region PR, and the +2 order light S₊₂, and the −2 order light S₋₂ are outside the pupil region PR. That is, the +2 order light S₊₂, and the −2 order light S₋₂ will be filtered out, and the 0 order light S₀, the +1 order light S₊₁, and the −1 order light S₋₁ will be directed to the semiconductor wafer.

As shown in FIG. 8B (the lateral axis of FIG. 8B has been normalized), based on the above concept, if we assume that the 0 order light S₀, the +1 order light S₊₁, the −1 order light S₋₁, the +2 order light S₊₂, and the −2 order light S₋₂ are all point-light, the +1 order light S₊₁, and the −1 order light S₋₁ may satisfy:

$$\frac{1}{p} < \frac{N A}{λ} \qquad ( 3 )$$

On the other hand, the +2 order light S₊₂, and the −2 order light S₋₂ may satisfy:

$$\frac{2}{p} > \frac{N A}{λ} \qquad ( 4 )$$

It is noted that 1/p is the distance between two adjacent diffracted lights, and NA/λ is the boundary of the pupil region PR. Based on the equations (2), (3), and (4), the k₁ factor may satisfy:

$$\frac{1}{4} \leq {k}_{1} \leq \frac{1}{2} \qquad ( 5 )$$

However, in practice, the light source may not be a point-light. The 0 order light S₀, the +1 order light S₊₁, the −1 order light S₋₁, the +2 order light S₊₂, and the −2 order light

S₋₂ may include a circular shape, and have a radius σ (or a diameter 2σ). In such embodiments, the equations (3) and (4) can be modified as:

$$\frac{1}{p} < \frac{N A}{λ} ( 1 - σ ) \qquad ( 6 )$$

$$\frac{2}{p} > \frac{N A}{λ} ( 1 + σ ) \qquad ( 7 )$$

Based on the equations (2), (6), and (7), the k₁ factor may satisfy:

$$\frac{1}{4 ( 1 - σ )} \leq {k}_{1} \leq \frac{2}{4 ( 1 + σ )} \qquad ( 8 )$$

FIG. 8C is a light source size (σ) versus k₁ factor and pitch plot in accordance with some embodiments of the present disclosure, in which the lateral axis (X-axis) represents light source size (σ), and the vertical axis (Y-axis) represents the k₁ factor of Rayleigh criterion and the minimum pitch size. FIG. 8C illustrates a curve C4 and a curve C5, in which the curve C4 can be expressed as:

$${k}_{1} = \frac{1}{4 ( 1 - σ )} \qquad ( 9 )$$

On the other hand, the curve C5 can be expressed as:

$${k}_{1} = \frac{2}{4 ( 1 + σ )} \qquad ( 10 )$$

In some embodiments, when an EUV mask (e.g., the EUV masks MA1, MA2, and MA3 as discussed) is used as a phase-only mask (POM), the light source size (e.g., the radius σ) on the pupil plane and the k₁ factor of the lithography system should be within the POM effective region. In some embodiments, the POM effective region is defined as the region that is above the curve C4 and below the curve C5. That is, when the light source size (e.g., the radius σ) on the pupil plane and the k1 factor of the lithography system are outside the POM effective region, the EUV mask cannot generate a double frequency effect as discussed above. The curve C4 and the curve C5 intersects at a point Q1 where the maximum value of the light source size (e.g., the radius σ_{Q1}) occurs. If the light source size is greater than the radius σ_{Q1}, the EUV mask may not generate double frequency effect.

Based on the POM effective region as shown in FIG. 8C, it can be understood that when the k₁ factor of the lithography system is determined, the light source size (e.g., the radius σ) can be selected to have a desired value. In some embodiments, the light source size (e.g., the radius σ) can be designed as large as possible to increase the light intensity, while still maintaining the lithography system being operated in the POM effective region. With such method, the lithography performance can be improved.

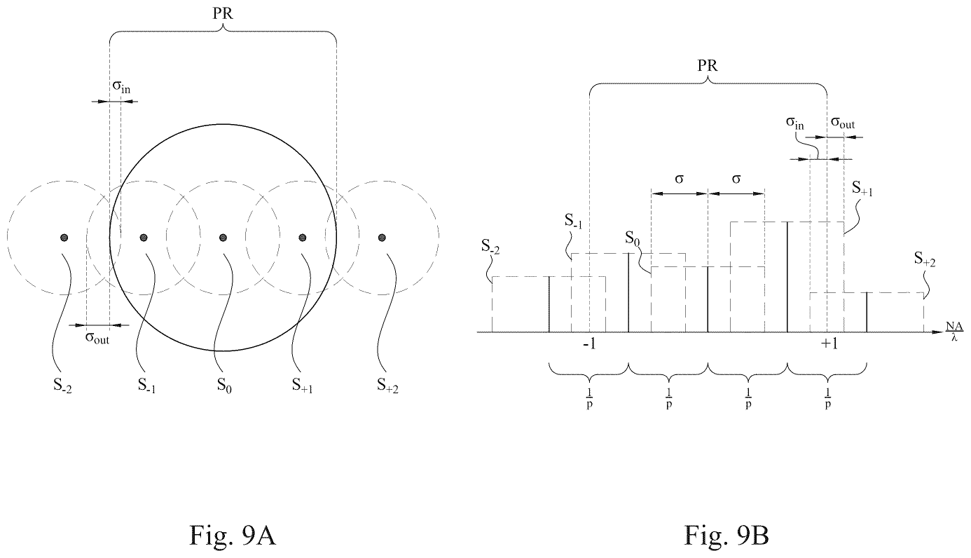

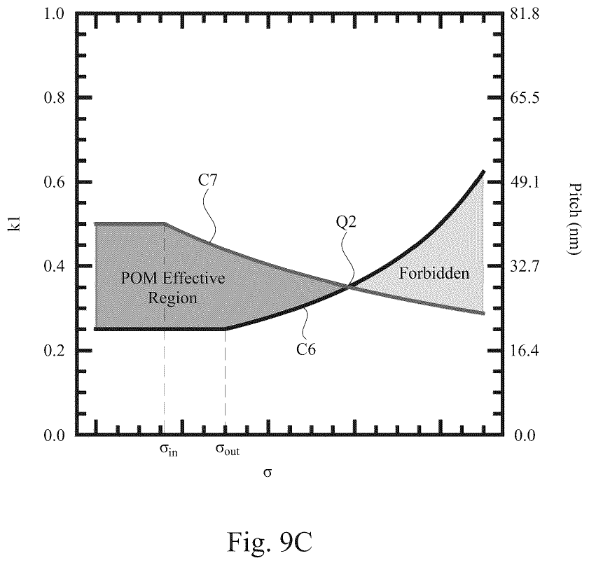

FIGS. 9A and 9B are schematic views of light source on a pupil plane in accordance with some embodiments of the present disclosure. As discussed in FIGS. 8A to 8C, to obtain a double frequency effect from the EUV mask, it is desired that the 0 order light S₀, the +1 order light S₊₁, and the −1 order light S₋₁ are within the pupil region PR, and the +2 order light S₊₂ and the −2 order light S₋₂ are outside the pupil region PR. Moreover, the k₁ factor may satisfy the equation (8).

However, based on the experiment result, it is observed that when the light source size (e.g., the radius σ) slightly exceeds the critical value (e.g., the radius σQ1 in FIG. 8C), the EUV mask can still provide double frequency effect. For example, the radius σQ1 in FIG. 8C is about 0.35, while the experiment result shows that when the radius σ is about 0.5, the EUV mask can still provide double frequency effect. That is, it is allowed that portions of the +1 order light S₊₁ and the −1 order light S₋₁ may be outside the pupil region PR, and portions of the +2 order light S₊₂, and the −2 order light S₋₂ are within the pupil region PR, and the EUV mask can still provide double frequency effect.

As shown in FIGS. 9A and 9B, the +1 order light S₊₁ and the −1 order light S₋₁ is allowed to extend outside the pupil region PR by a predetermined value Gout, and the +2 order light S₊₂, and the −2 order light S₋₂ is allowed to extend into the pupil region PR by a predetermined value Fin. Based on the experiment results, the predetermined value Gout may be greater than the predetermined value Fin. In some embodiments, the predetermined value σₒᵤₜ may be 0.3, and the predetermined value σᵢₙ may be 0.16. In such embodiments, the equations (6) and (7) can be modified as:

$$\frac{1}{p} < \frac{N A}{λ} ( 1 + {σ}_{o u t} - σ ) \qquad ( 11 )$$

$$\frac{2}{p} > \frac{N A}{λ} ( 1 - {σ}_{i n} + σ ) \qquad ( 12 )$$

Based on the equations (2), (11), and (12), the k₁ factor may satisfy:

$$\frac{1}{4 ( 1 + {σ}_{o u t} - σ )} \leq {k}_{1} \leq \frac{2}{4 ( 1 - {σ}_{i n} + σ )} \qquad ( 13 )$$

FIG. 9C is a light source size (σ) versus k₁ factor and pitch plot in accordance with some embodiments of the present disclosure, in which the lateral axis (X-axis) represents light source size (σ), and the vertical axis (Y-axis) represents the k₁ factor of Rayleigh criterion and the minimum pitch size. FIG. 9C illustrates a curve C6 and a curve C7, in which the curve C6 can be expressed as:

$${k}_{1} = \{ \begin{matrix}\frac{1}{4} & for σ \leq {σ}_{out} \\ \frac{1}{4 ( 1 + {σ}_{out} - σ )} & for σ > {σ}_{out}\end{matrix} \qquad ( 14 )$$

On the other hand, the curve C7 can be expressed as:

$${k}_{1} \{ \begin{matrix}\frac{1}{4} & for σ \leq {σ}_{out} \\ \frac{1}{4 ( 1 + {σ}_{out} - σ )} & for σ > {σ}_{out}\end{matrix} \qquad ( 15 )$$

In some embodiments, when an EUV mask (e.g., the EUV masks MA1, MA2, and MA3 as discussed) is used as a phase-only mask (POM), the light source size (e.g., the radius σ) on the pupil plane and the k₁ factor of the lithography system should be within the POM effective region. In some embodiments, the POM effective region is defined as the region that is above the curve C6 and below the curve C7. That is, when the light source size (e.g., the radius σ) on the pupil plane and the k₁ factor of the lithography system are outside the POM effective region, the EUV mask cannot generate a double frequency effect as discussed above.

Based on the POM effective region as shown in FIG. 9C, it can be understood that when the k₁ factor of the lithography system is determined, the light source size (e.g., the radius σ) can be selected to have a desired value. In some embodiments, the light source size (e.g., the radius σ) can be designed as large as possible to increase the light intensity, while still maintaining the lithography system being operated in the POM effective region. With such method, the lithography performance can be improved.

As mentioned above, the predetermined value Gout may be greater than the predetermined value σᵢₙ. In some embodiments, the predetermined value Gout may be 0.3, and the predetermined value Gin may be 0.16. Accordingly, the POM effective region can be broken down at different ranges of the light source size (e.g., the radius σ).

When the light source size (e.g., the radius σ) is greater than the predetermined value σₒᵤₜ (e.g., σ>σₒᵤₜ), the k₁ factor may satisfy:

$$\frac{1}{4 ( 1 + {σ}_{o u t} - σ )} \leq {k}_{1} \leq \frac{2}{4 ( 1 - {σ}_{i n} + σ )} \qquad ( 16 )$$

When the light source size (e.g., the radius σ) is less than the predetermined value σₒᵤₜ and is greater than the predetermined value σᵢₙ (e.g., σᵢₙ<σ<σₒᵤₜ), the k₁ factor may satisfy:

$$\frac{1}{4} \leq {k}_{1} \leq \frac{2}{4 ( 1 - {σ}_{i n} + σ )} \qquad ( 17 )$$

When the light source size (e.g., the radius σ) is less than the predetermined value σᵢₙ (e.g., σ<σᵢₙ), the k₁ factor may satisfy:

$$\frac{1}{4} \leq {k}_{1} \leq \frac{1}{2} \qquad ( 18 )$$

The curve C6 and the curve C7 intersects at a point Q2 where the maximum value of the light source size (e.g., the radius σ) occurs. In some embodiments, the point Q2 occurs when the light source size (e.g., the radius σ) is about 0.587 and the k₁ factor is about 0.35, and the corresponding minimum pitch size may be about 28.63 nm.

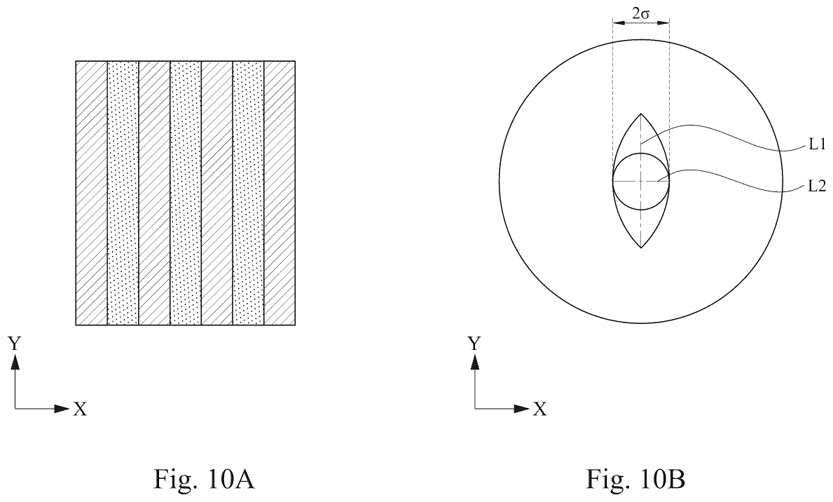

FIG. 10A is a schematic view of a pattern of an EUV mask in accordance with some embodiments of the present disclosure. FIG. 10B is schematic views of light source on a pupil plane in accordance with some embodiments of the present disclosure. Based on the above discussion with respect to FIGS. 9A to 9C, it can be understood that for a given k1 factor, one can obtain a desired value of light source size, such that the lithography system can be operated in the POM effective region.

In FIG. 10A, shown there is an exemplary pattern of an EUV mask. In some embodiments, the pattern of an EUV mask is a vertical line pattern, in which the line pattern extends along a first direction (e.g., Y-direction). Accordingly, the vertical line pattern of the EUV mask will be transferred to a layer of a semiconductor wafer, such that the patterned layer on the semiconductor wafer may also include a vertical line pattern, in which the line pattern extends along a first direction (e.g., Y-direction). In some embodiments, the EUV mask is a phase-only-mask (POM), and the vertical line pattern of the EUV mask will be transferred to the layer of a semiconductor wafer using the double frequency method as discussed in FIGS. 2A to 2D and 3A to 3D.

In FIG. 10B, when the EUV mask is a phase-only-mask (POM), the light source size on the pupil region can be estimated according to the method as discussed in FIGS. 9A to 9C. As discussed in FIGS. 9A to 9C, the light source projected on the pupil region has a circular shape. In FIG. 10B, the shape of the light source can be enlarged along the first direction (e.g., Y-direction), such that the light source is enlarged from a circular shape to an ellipse-like shape with pointed ends, while the lithography system can still be operated in the POM effective region. In some embodiments, the area of the light source can be expressed as:

Area=2*(cos⁻¹(1−σ)−sin(cos⁻¹(1−σ))*(1−σ)) (19)

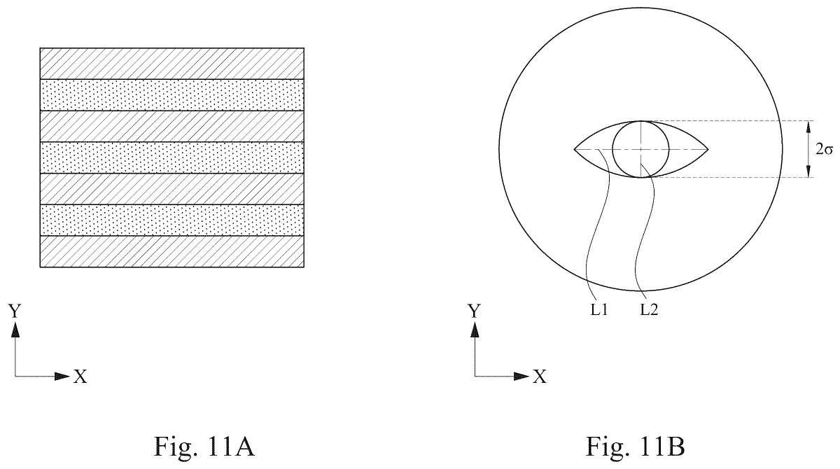

The ellipse-like shape may include a major axis L1 along the first direction (e.g. Y-direction), and a minor axis L2 along the second direction (e.g. X-direction) that is perpendicular to the first direction. Here, σ is half the minor axis L2 of the ellipse-like shape. That is, the minor axis L2 of the ellipse-like shape may be equal to 20. FIG. 11A is a schematic view of a pattern of an EUV mask in accordance with some embodiments of the present disclosure. FIG. 11B is schematic views of light source on a pupil plane in accordance with some embodiments of the present disclosure. Based on the above discussion with respect to FIGS. 9A to 9C, it can be understood that for a given k1 factor, one can obtain a desired value of light source size, such that the lithography system can be operated in the POM effective region.

In FIG. 11A, shown there is an exemplary pattern of an EUV mask. In some embodiments, the pattern of an EUV mask is a horizontal line pattern, in which the line pattern extends along a second direction (e.g., X-direction). Accordingly, the horizontal line pattern of the EUV mask will be transferred to a layer of a semiconductor wafer, such that the patterned layer on the semiconductor wafer may also include a horizontal line pattern, in which the line pattern extends along a second direction (e.g., X-direction). In some embodiments, the EUV mask is a phase-only-mask (POM), and the vertical line pattern of the EUV mask will be transferred to the layer of a semiconductor wafer using the double frequency method as discussed in FIGS. 2A to 2D and 3A to 3D.

In FIG. 11B, when the EUV mask is a phase-only-mask (POM), the light source size on the pupil region can be estimated according to the method as discussed in FIGS. 9A to 9C. As discussed in FIGS. 9A to 9C, the light source projected on the pupil region has a circular shape. In FIG. 11B, the shape of the light source can be enlarged along the second direction (e.g., X-direction), such that the light source is enlarged from a circular shape to an ellipse-like shape with pointed ends, while the lithography system can still be operated in the POM effective region. In some embodiments, the area of the light source can be expressed as:

Area=2*(cos⁻¹(1−σ)−sin(cos⁻¹(1−σ))*(1−σ)) (20)

The ellipse-like shape may include a major axis L1 along the first direction (e.g. X-direction), and a minor axis L2 along the second direction (e.g. Y-direction) that is perpendicular to the first direction. Here, σ is half the minor axis L2 of the ellipse-like shape. That is, the minor axis L2 of the ellipse-like shape may be equal to 2σ.

TABLE 1

| σ | k₁ | Pitch (CD) | |
|---|---|---|---|
| 0 | 0.25~0.50 | 20.45~40.9 | nm |
| 0.2 | 0.25~0.48 | 20.45~39.34 | nm |
| 0.313 | 0.253~0.433 | 20.72~35.48 | nm |
| 0.44 | 0.29~0.39 | 23.78~31.96 | nm |
| 0.587 | 0.35 | 28.68 | nm |

For example, table 1 shows different conditions of the light source size (e.g., σ), the corresponding k1 factor, and the corresponding pitch (CD) that can be printed on a semiconductor wafer. Here, when the light source is the circular shape as discussed in FIG. 9A, the σ may be the radius of the circular shape. If the light source is the ellipse-like shape as discussed in FIGS. 10B and 11B, the σ may be half the minor axis of the ellipse-like shape.

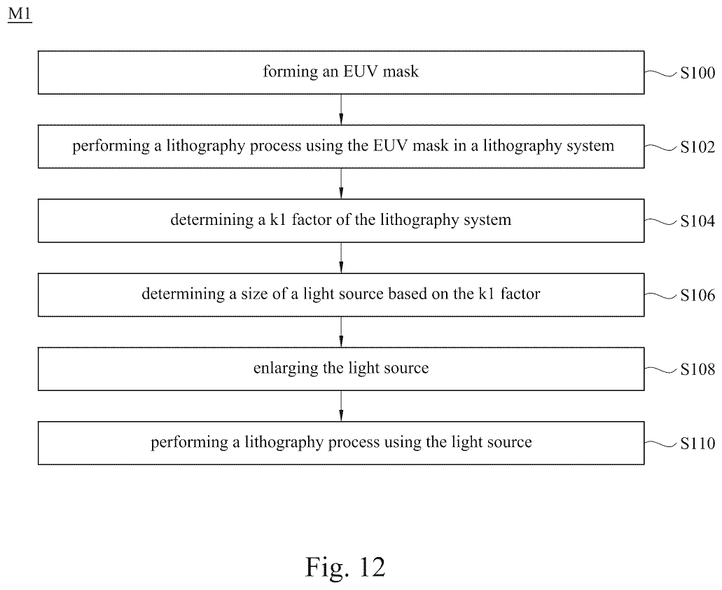

FIG. 12 illustrates a method for operating a lithography system in accordance with some embodiments of the disclosure. A method M 1 is provided, and the method M 1 will be discussed in conjunction with FIGS. 1 to 11B. Although the method M 1 is described as a series of acts, it will be appreciated that these acts are not limiting in that the order of the acts can be altered in other embodiments. In other embodiments, some acts that are illustrated and/or described may be omitted in whole or in part.

The method M 1 starts from step S₁₀₀ by forming an EUV mask. In some embodiments, the EUV mask can be the EUV masks MA1, M A 2, M A 3 as discussed above, and the formation thereof can be similar to those described in FIGS. 7A to 7D.

The method M 1 proceeds to step S₁₀₂ by performing a lithography process using the EUV mask in a lithography system. For example, the EUV mask can be used as the photomask 220 of the lithography system 10 as discussed in FIG. 1.

The method M 1 proceeds to step S₁₀₄ by determining a k₁ factor of the lithography system. For example, the k₁ factor can be determined based on the results of the lithography process as discussed above.

The method M 1 proceeds to step S₁₀₆ by determining a size of a light source based on the k₁ factor. For example, the light source size can be determined based on the method as discussed above with respect to FIGS. 9A to 9C.

The method M 1 proceeds to step S₁₀₈ by enlarging the light source. For example, the light source size can be enlarged based on the method as discussed above with respect to FIGS. 10A to 10B and 11A to 11B.

The method M 1 proceeds to step S₁₁₀ by performing a lithography process using the light source. For example, the light source can be the ellipse-like shape with pointed ends light source as discussed above. In some embodiments, the step S₁₀₈ can be omitted, and the light source can be the circular shape light source as discussed above.

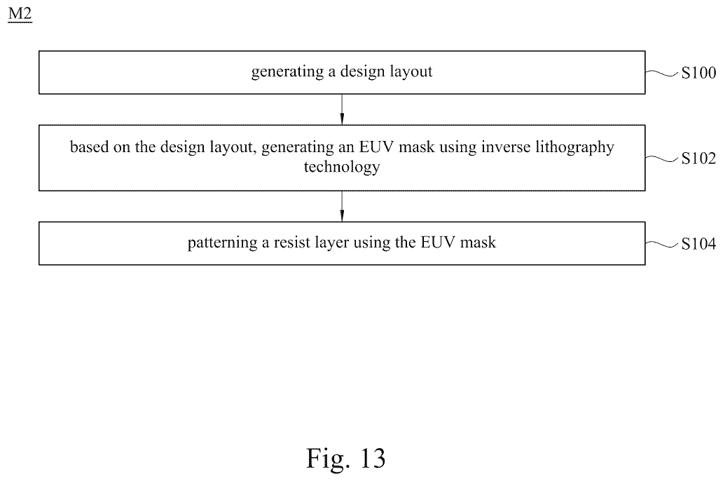

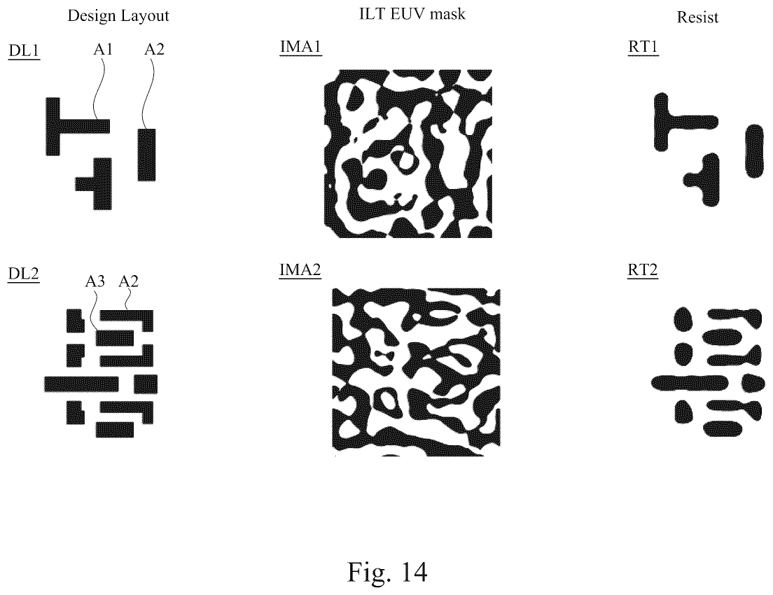

FIG. 13 illustrates a lithography method in accordance with some embodiments of the disclosure. FIG. 14 illustrates schematic views at various stages of a lithography method in accordance with some embodiments of the disclosure. In FIG. 13, a method M 2 is provided, and the method M 2 will be discussed in conjunction with FIG. 14. Although the method M 2 is described as a series of acts, it will be appreciated that these acts are not limiting in that the order of the acts can be altered in other embodiments. In other embodiments, some acts that are illustrated and/or described may be omitted in whole or in part.

The method M 2 starts from step S₂₀₀ by generating a design layout. In some embodiments, the design layout includes various IC features (represented by geometrical shapes) designed for an IC product based on specifications of an IC product to be manufactured. The design layout is presented in one or more data files having information of the target pattern. For example, the design layout is generated in a GDSII file format or an OASIS file format. In some embodiments, a portion of the design layout includes various IC features to be formed in a wafer (for example, a silicon substrate) and/or in various material layers disposed on the wafer.

As shown in FIG. 14, shown there are two exemplary design layouts PT1 and PT2, in which each of the design layouts PT1 and PT2 may include patterns that are arranged in a non-periodic manner. For example, the design layout PT1 may include at least one T-shape pattern A 1 and at least one line-shape pattern A 2. On the other hand, the design layout PT2 may include at least one line-shape pattern A 2 and at least one L-shape pattern A 3. In other embodiments, a design layout may include a plurality of T-shape patterns A 1, line-shape patterns A 2, L-shape patterns A 3, other patterns, or irregular-shape patterns.

The method M 2 proceeds to step S₂₀₂ by based on the design layout, generating an EUV mask using inverse lithography technology. In some embodiments, the inverse lithography technology (ILT) includes simulating the optical lithography process in a reverse direction, using the design layout as an input to the simulations. The ILT process may produce complex, curvilinear patterns on a photomask or reticle.

As shown in FIG. 14, shown there are two exemplary EUV masks IM A 1 and IM A 1, the EUV masks IMA1 and IMA2 are generated, using inverse lithography technology, according to the design layouts PT1 and PT2, respectively. In some embodiments, the EUV masks IM A 1 and IM A 2 may include similar configurations as the EUV masks MA1, MA2, and MA3 as discussed above. That is, the EUV masks IMA1 and IM A 2 can be phase-only-mask (POM) as discussed above.

The method M 2 proceeds to step S₂₀₄ by patterning a resist layer using the EUV mask. The EUV masks IM A 1 and IM A 2 of FIG. 14 may be used to pattern a resist layer over a substrate. As shown in FIG. 14, shown there are two exemplary resist layers RT1 and RT2, in which each of the resist layers RT1 and RT2 may be patterned using the EUV masks IMA1 and IMA2, respectively. As shown in FIG. 14, it can be seen that the patterned resist layers RT1 and RT2 may include similar patterns as the design layouts PT1 and PT2, respectively.

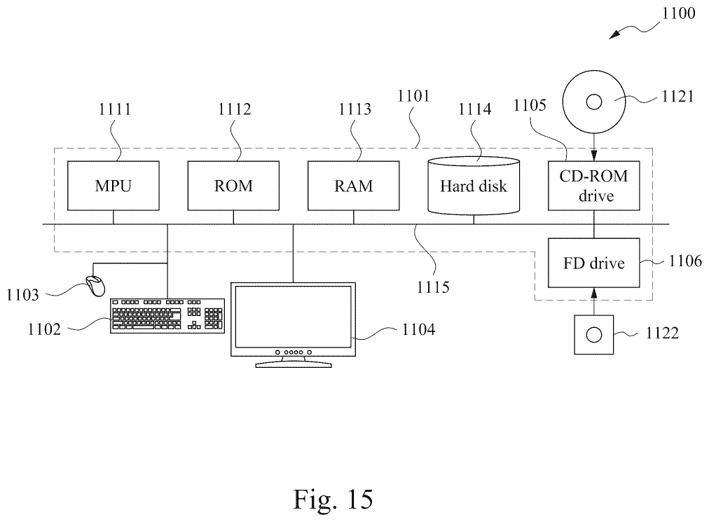

FIG. 15 illustrates an apparatus for operating a lithography system in accordance with some embodiments of the disclosure. FIG. 15 is a schematic view of a computer system 1100 that executes the process for operating the lithography system according to one or more embodiments as described above. All of or a part of the processes, method and/or operations of the foregoing embodiments can be realized using computer hardware and computer programs executed thereon. For example, the computer system 1100 may be electrically connected to the lithography system 10 as discussed in FIG. 1, and the computer system 1100 may be able to control the lithography system 10 to perform a lithography process. Moreover, the computer system 1100 may be able to perform the method M 1 as discussed in FIG. 12 and the method M 2 as discussed in FIG. 13.

The operations include every part of the mask optimization module 300 and the training systems 500 and 600. In FIG. 15, a computer system 1100 is provided with a computer 1101 including an optical disk read only memory (e.g., CD-ROM or DVD-ROM) drive 1105 and a magnetic disk drive 1106, a keyboard 1102, a mouse 1103, and a monitor 1104. In greater detail, the computer 1101 is provided with, in addition to the optical disk read only memory drive 1105 and the magnetic disk drive 1106, one or more processors, such as a micro processing unit (M PU) 1111, a ROM 1112 in which a program, such as a boot up program is stored, a random access memory (RAM) 1113 that is connected to the M PU 1111 and in which a command of an application program is temporarily stored and a temporary storage area is provided, a hard disk 1114 in which an application program, a system program, and data are stored, and a bus 1115 that connects the M PU 1111, the ROM 1112, and the like. Note that the computer 1101 may include a network card (not shown) for providing a connection to a LAN.

The program for causing the computer system 1100 to control the lithographic system in the foregoing embodiments may be stored in an optical disk 1121 or a magnetic disk 1122, which are inserted into the optical disk read only memory drive 1105 or the magnetic disk drive 1106, and transmitted to the hard disk 1114. Alternatively, the program may be transmitted via a network (not shown) to the computer 1101 and stored in the hard disk 1114. At the time of execution, the program is loaded into the RAM 1113. The program may be loaded from the optical disk 1121 or the magnetic disk 1122, or directly from a network. The program does not necessarily have to include, for example, an operating system (OS) or a third party program to cause the computer 1101 to execute the process for manufacturing the lithographic mask of a semiconductor device in the foregoing embodiments. The program may only include a command portion to call an appropriate function (module) in a controlled mode and obtain desired results.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a phase-only-mask (POM) and formation method thereof. The POM can provide double frequency effect to reduce critical dimension. Moreover, embodiments of the present disclosure provide a method to modify the size of the light source while maintaining the lithography system being operated in a POM effective region.

In some embodiments of the present disclosure, a method includes forming a reflective multilayer over a substrate; forming a capping layer over the reflective multilayer; and forming an absorber layer over the capping layer, wherein the absorber comprises a first material having a reflectivity R₁ satisfying:

$${R}_{1} = exp ( \frac{- 2 π {ε}_{1}}{1 - {n}_{1}} ) \geq 50 \%$$

wherein n₁ is a refractive index of the first material and ε₁ is an extinction coefficient of the first material.

In some embodiments, the first material the absorber layer exposes portions of the capping layer.

In some embodiments, the absorber layer further comprises a second material, wherein second material has a refractive index n₂ in a range from about 0.86 to about 0.999, and an extinction coefficient 82 in a range from about 0 to about 0.0155.

In some embodiments, the first material and the second material has a same thickness.

In some embodiments, the absorber layer further comprises a second material, wherein second material has a refractive index n₂ in a range from about 0.86 to about 0.999, and an extinction coefficient 82 in a range from about 0 to about 0.864.

In some embodiments, the second material is thicker than the first material.

In some embodiments, forming the absorber layer comprises etching back the first material such that a top surface of the first material is lower than a top surface of the second material.

In some embodiments of the present disclosure, a method includes performing a lithography process using a lithography system; determining a k₁ factor of Rayleigh criterion of the lithography system; and determining a size σ of a light source of the lithography process based on the k₁ factor, wherein the size σ of the light source and the k₁ factor satisfy:

$$\frac{1}{4 ( 1 + {σ}_{o u t} - σ )} \leq {k}_{1} \leq \frac{2}{4 ( 1 - {σ}_{i n} + σ )}$$

wherein σₒᵤₜ is a first predetermined value, and σᵢₙ is a second predetermined value; and performing another lithography process using the light source.

In some embodiments, the lithography process is performed using an EUV mask, and wherein an absorber layer of the EUV mask has a first material that has a reflectivity greater than or equal to 50%.

In some embodiments, the absorber layer of the EUV mask has a second material that has a reflectivity greater than or equal to 50%, and wherein the first material is different from the second material.

In some embodiments, the first predetermined value Cout is greater than the second predetermined value σᵢₙ.

In some embodiments, the first predetermined value Gout is 0.3 and the second predetermined value Gin is 0.16.

In some embodiments, the light source has a circular shape, wherein a radius of the light source is equal to the size σ.

In some embodiments, the method further includes enlarging the light source from a circular shape to an ellipse-like shape with pointed ends.

In some embodiments, wherein an area of the ellipse-like shape is expressed as:

area=2*(cos⁻¹(1−σ)−sin(cos⁻¹(1−σ))*(1−σ)).

In some embodiments of the present disclosure, an EUV mask includes a substrate; a reflective multilayer over the substrate; a capping layer over the reflective multilayer; and an absorber layer over the capping layer, the absorber layer comprising a first material and second material, wherein one of the first material and the second material has a reflectivity greater than or equal to 50%.

In some embodiments, the first material and the second material have a same thickness.

In some embodiments, the first material and the second material have different thicknesses.

In some embodiments, a reflectivity R₁ of the first material satisfies:

$${R}_{1} = exp ( \frac{- 2 π {ε}_{1}}{1 - {n}_{1}} ) \geq 50 \%$$

wherein n₁ is a refractive index of the first material and ε₁ is an extinction coefficient of the first material, and the second material has a refractive index n₂ in a range from about 0.86 to about 0.999, and an extinction coefficient 82 in a range from about 0 to about 0.0155.

In some embodiments, a reflectivity R₁ of the first material satisfies:

$${R}_{1} = exp ( \frac{- 2 π {ε}_{1}}{1 - {n}_{1}} ) \geq 50 \%$$

wherein n₁ is a refractive index of the first material and ε₁ is an extinction coefficient of the first material, and the second material has a refractive index n₂ in a range from about 0.86 to about 0.999, and an extinction coefficient 82 in a range from about 0 to about 0.864.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a reflective multilayer over a substrate;
forming a capping layer over the reflective multilayer; and
forming an absorber layer over the capping layer, wherein the absorber layer comprises a first material having a reflectivity R₁ satisfying:
$${R}_{1} = exp ( \frac{- 2 π {ε}_{1}}{1 - {n}_{1}} ) \geq 50 \%$$
wherein n₁ is a refractive index of the first material and ε₁ is an extinction coefficient of the first material.

2. The method of claim 1, wherein the first material the absorber layer exposes portions of the capping layer.

3. The method of claim 1, wherein the absorber layer further comprises a second material, wherein second material has a refractive index n₂ in a range from about 0.86 to about 0.999, and an extinction coefficient 82 in a range from about 0 to about 0.0155.

4. The method of claim 3, wherein the first material and the second material has a same thickness.

5. The method of claim 1, wherein the absorber layer further comprises a second material, wherein second material has a refractive index n₂ in a range from about 0.86 to about 0.999, and an extinction coefficient 82 in a range from about 0 to about 0.864.

6. The method of claim 5, wherein the second material is thicker than the first material.

7. The method of claim 5, wherein forming the absorber layer comprises etching back the first material such that a top surface of the first material is lower than a top surface of the second material.

8. A method, comprising:
performing a lithography process using a lithography system;
determining a k₁ factor of Rayleigh criterion of the lithography system; and
determining a size σ of a light source of the lithography process based on the k₁ factor, wherein the size σ of the light source and the k₁ factor satisfy:
$$\frac{1}{4 ( 1 + {σ}_{o u t} - σ )} \leq {k}_{1} \leq \frac{2}{4 ( 1 - {σ}_{i n} + σ )}$$
wherein σₒᵤₜ is a first predetermined value, and Fin is a second predetermined value; and
performing another lithography process using the light source.

9. The method of claim 8, wherein the lithography process is performed using an EUV mask, and wherein an absorber layer of the EUV mask has a first material that has a reflectivity greater than or equal to 50%.

10. The method of claim 9, wherein the absorber layer of the EUV mask has a second material that has a reflectivity greater than or equal to 50%, and wherein the first material is different from the second material.

11. The method of claim 8, wherein the first predetermined value Gout is greater than the second predetermined value σᵢₙ.

12. The method of claim 11, wherein the first predetermined value Gout is 0.3 and the second predetermined value σᵢₙ is 0.16.

13. The method of claim 8, wherein the light source has a circular shape, wherein a radius of the light source is equal to the size σ.

14. The method of claim 13, further comprising enlarging the light source from a circular shape to an ellipse-like shape with pointed ends.

15. The method of claim 14, wherein an area of the ellipse-like shape is expressed as:
area=2*(cos⁻¹(1−σ)−sin(cos⁻¹(1−σ))*(1−σ)).

16. An EUV mask, comprising:
a substrate;
a reflective multilayer over the substrate;
a capping layer over the reflective multilayer; and
an absorber layer over the capping layer, the absorber layer comprising a first material and second material, wherein one of the first material and the second material has a reflectivity greater than or equal to 50%.

17. The EUV mask of claim 16, wherein the first material and the second material have a same thickness.

18. The EUV mask of claim 16, wherein the first material and the second material have different thicknesses.

19. The EUV mask of claim 16, wherein a reflectivity R1 of the first material satisfies:
$${R}_{1} = exp ( \frac{- 2 π {ε}_{1}}{1 - {n}_{1}} ) \geq 50 \%$$
wherein n₁ is a refractive index of the first material and ai is an extinction coefficient of the first material, and
the second material has a refractive index n₂ in a range from about 0.86 to about 0.999, and an extinction coefficient 82 in a range from about 0 to about 0.0155.

20. The EUV mask of claim 16, wherein a reflectivity R₁ of the first material satisfies:
$${R}_{1} = exp ( \frac{- 2 π {ε}_{1}}{1 - {n}_{1}} ) \geq 50 \%$$
wherein n₁ is a refractive index of the first material and ε₁ is an extinction coefficient of the first material, and
the second material has a refractive index n₂ in a range from about 0.86 to about 0.999, and an extinction coefficient ε₂ in a range from about 0 to about 0.864.
